(19) United States
(12) Patent Application Publication
(10) Pub. No.: US 2010/0053923 A1
(43) Pub. Date: Mar. 4, 2010

(54) SEMICONDUCTOR DEVICE AND CIRCUIT BOARD ASSEMBLY

(75) Inventors: Noriyuki Matsui, Kawasaki (JP); Hidehisa Sakai, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/486,084

(22) Filed: Jun. 17, 2009

(30) Foreign Application Priority Data
Aug. 26, 2008 (JP) 2008-217150

(51) Int. Cl. H05K 7/00; H01L 23/488

(52) U.S. Cl. 361/783; 257/690; 257/737; 257/E23.023

(57) ABSTRACT

A semiconductor device that includes a semiconductor element, a package substrate, and a plurality of bonding members. The semiconductor element is fixed on the front surface of the package substrate. The package substrate has a first region and a second region on the back surface. The plurality of bonding members is arranged in a grid pattern on the first region of the back surface of the package substrate. The second region of the package substrate defines a bonding prohibition region corresponding with the periphery of the semiconductor element in a plan view.

### CROSS-REFERENCE TO RELATED APPLICATION

This application is based upon and claims the benefit of priority of the prior Japanese Patent Application No. 2008-217150, filed on Aug. 26, 2008, the entire contents of which are incorporated herein by reference.

### FIELD

The present invention relates to a semiconductor device and a circuit board assembly including the semiconductor device.

### BACKGROUND

A semiconductor device such as SRAM (Static Random Access Memory) and ASIC (Application Specific Integrated Circuit) has numerous signal lines for sending and receiving information to and from external devices. Generally, a surface-mount technology is applied to the semiconductor device such as BGA (Ball Grid Array) to efficiently conduct electrical signals within a limited area to a printed circuit board (PCB) on which the semiconductor device is placed.

The BGA is a package with one face covered with solder balls in a grid pattern. In a BGA, the solder balls are stuck to the bottom of the package. The device is placed on the PCB that has copper pads in a pattern that matches the solder balls. The assembly which is formed with the PCB and the package is then heated, either in a reflow oven or by an infrared heater, causing the solder balls to melt. Surface tension causes the molten solder to hold the package in alignment with the circuit board, at the correct separation distance, while the solder is cooled and solidified.

Generally, while the assembly is heated and cooled, the PCB is warped, due to a difference in coefficient of thermal expansion between the PCB substrate and the BGA, which may cause the solder joints to fracture and disconnect.

As a way to prevent the fracture and disconnect of the solder joints, Japanese Laid-open Patent Publication No. 2006-165088, discloses the outermost solder balls on the bottom of the BGA chip carrier are replaced by conductive resin balls.

However, since a particular material such as conductive resin is employed instead of solder, a process of manufacturing the specific BGA package may be complicated. Furthermore, the process condition of joining the specific BGA to the PCB substrate may be changed.

On the other hand, Japanese Laid-open Patent Publication No. 2005-183868 discloses a chip scale package (CSP) with corners on the bottom of the CSP chip carrier which do not provide a solder ball.

However, since there are no bumps at the corners on the bottom of the CSP chip carrier, the CSP according to JP-A-2005-183868 may have a disadvantage condition in multiterminal joint in that the CSP chip has limited space for disposing solder balls, and a pitch between solder balls is finite to a extent.

### SUMMARY

According to an aspect of the present invention, a semiconductor device includes a semiconductor element, a package substrate, and a plurality of bonding members. The semiconductor element is fixed on the front surface of the package substrate. The package substrate has a first region and a second region on the back surface. The plurality of bonding members is arranged in a grid pattern on the first region of the back surface of the package substrate. The second region of the package substrate defines a bonding prohibition region corresponding with the periphery of the semiconductor element in a plan view.

It is to be understood that both the foregoing general description and the following detailed description are exemplary, and are not restrictive of the invention, as claimed.

### BRIEF DESCRIPTION OF DRAWINGS

The above and other objects, features and advantages of the present invention will become apparent from the following description of the preferred embodiments in conjunction with the accompanying drawings, wherein:

FIG. 1A is a schematic plan view of a circuit board assembly according to one embodiment of the invention;

FIG. 1B is a cross-sectional view of the circuit board assembly depicted in FIG. 1A taken along line A-A;

FIG. 2A is a schematic plan view of the semiconductor device according to the embodiment;

FIG. 2B is a schematic plan view of the bottom of the semiconductor device in FIG. 2A;

FIG. 2C is a cross-sectional view of the semiconductor device 3 depicted in FIGS. 2A and 2B taken along line B-B;

FIG. 3 is a schematic plan view of a circuit board according to the embodiment before the semiconductor device in FIG. 2 is mounted;

FIG. 4 is a cross-sectional view of a circuit board assembly according to a comparative example;

FIG. 5 is a table showing the materials, Young's moduli, Poisson ratios, and linear expansion coefficients of components used in a simulation;

FIG. 6 illustrates an arrangement of bonding members in the circuit board assembly according to the comparative example;

FIG. 7 illustrates an arrangement of bonding members in the circuit board assembly according to the embodiment of the invention;

FIG. 8 is a table showing the distortion and stress values according to the simulation; and

FIG. 9 is a graph comparing the distortion ratio obtained in the comparative example and the embodiment of the present invention.

### DESCRIPTION OF EMBODIMENTS

Hereinafter, one embodiment of the present invention will be described with reference to the accompanying drawings.

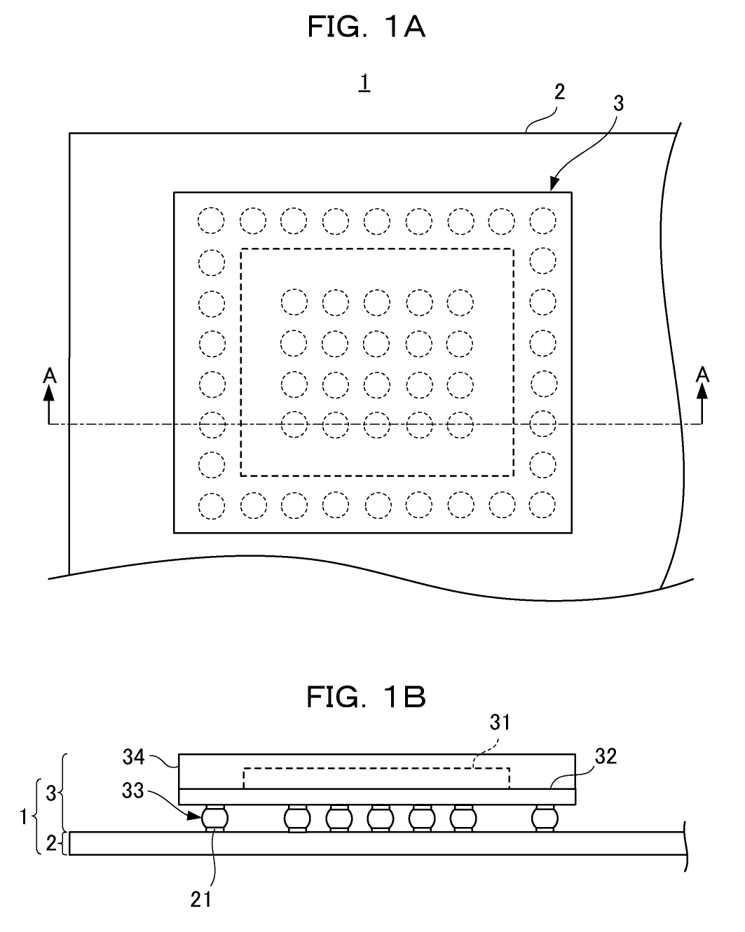

FIG. 1A is a schematic plan view of the circuit board assembly 1 according to one embodiment of the invention. FIG. 1B is a cross-sectional view of the circuit board assembly 1 depicted in FIG. 1A taken along line A-A. For the sake of convenience, hatch lines are omitted from the cross-sectional view.

The circuit board assembly 1 depicted in FIG. 1 is embedded in an electronic apparatus, for example a personal computer and controls various operations of the apparatus. The circuit board assembly 1 includes a printed circuit board 2 whereupon electronic circuits have been formed by patterning copper traces, and a semiconductor device 3 mounted on the printed circuit board 2.

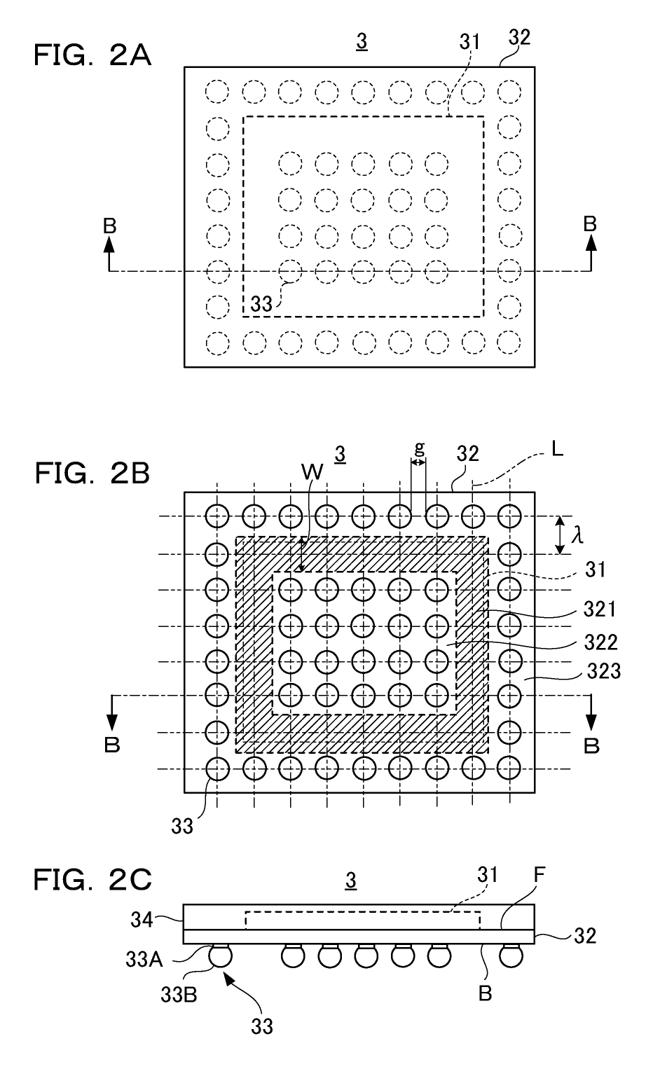

FIG. 2A is a schematic plan view of the semiconductor device 3. FIG. 2B is a schematic plan view of the bottom of the semiconductor device 3. FIG. 2C is a cross-sectional view of the semiconductor device 3 depicted in FIGS. 2A and 2B taken along line B-B.

The semiconductor device 3 depicted in FIG. 2 includes a semiconductor element 31, a package substrate 32, a plurality of bonding members 33 and a mold 34. The semiconductor element 31 is fixed on the surface F of the package substrate 32. The plurality of bonding members 33 is arranged on the bottom B of the package substrate 32. The mold 34 covers the semiconductor element 31 and the package substrate 32. The semiconductor device 3 may function as an SRAM, a CPU and/or an ASIC.

The semiconductor element 31 is a silicon microchip, and chip pads (not shown) are interconnected to an SRAM circuit.

The package substrate 32 is formed of resin and has a shape of a rectangular plate. The semiconductor element 31 is fixed on the surface F of the package substrate 32, and is electrically connected to the package substrate 32 by wire bonding method, for example. Alternatively, the semiconductor element 31 may be electrically connected to the package substrate 32 by flip chip method.

The bonding members 33 are arranged in a two-dimensional array on the bottom B of the package substrate 32. Each of the bonding members 33 has a pad 33A formed on the bottom B of the package substrate 32 and a solder ball 33B provided on the pad 33A. Each pad 33A is electrically connected to the semiconductor element 31 through conductor patterns and bonding pads (not shown) formed on the package substrate 32.

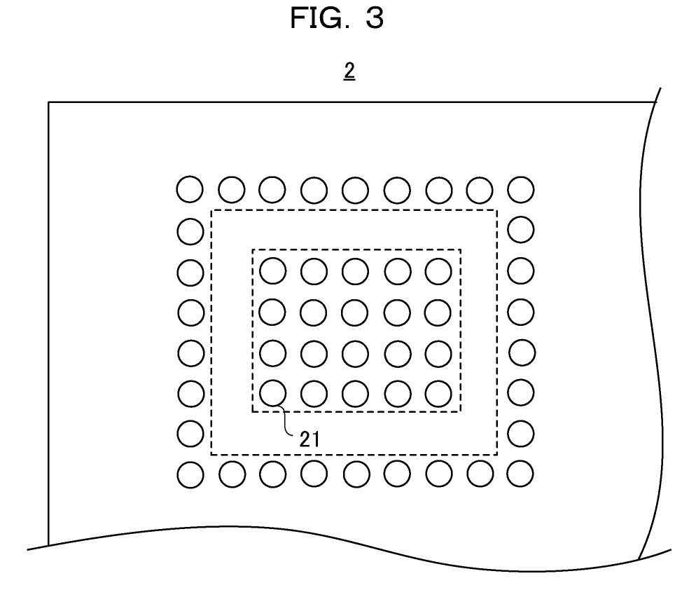

FIG. 3 is a schematic plan view of the printed circuit board 2 before the semiconductor device 3 is mounted. Terminals 21 are arranged on the printed circuit board 2 each of which matches the bonding members 33 depicted in FIG. 2.

When the semiconductor device 3 depicted in FIG. 2 is placed on the printed circuit board 2, the solder balls 33B of the semiconductor device 3 are stuck to the terminals 21 of printed circuit board 2. The assembly of the printed circuit board 2 and the semiconductor device 3 is then heated in a reflow oven, for example, and the solder balls are molten. Surface tension causes the molten solder to hold the semiconductor device 3 in alignment with the printed circuit board 2 while the solder is cooled and solidified. The circuit board assembly 1 depicted in FIG. 1 is completed.

The bonding members 33 are arranged at separation distance “g” on the bottom B of the package substrate 32 as depicted in FIG. 2B. However, the bonding members 33 are not uniformly arranged over the bottom B. In particular, the package substrate 32 has, on the bottom B, a bonding prohibition region 321, indicated by hatch lines, and bonding regions 322, 323. No bonding members 33 are placed in the bonding prohibition region 321. The bonding prohibition region 321 is a band-like region that overlaps the periphery of the semiconductor element 31 in a plan view. The bonding members 33 are disposed only within the bonding regions 322 and 323. The bonding regions may be regarded as a first region in the invention, and the bonding prohibition region may be regarded as a second region in the invention. The width W of the bonding prohibition region 321 is greater than a width where a bonding member can be disposed. Therefore, opposing bonding members 33 across the width W can be reliably located away from each other despite a mounting tolerance such that a short circuit can be prevented.

Specifically, the bonding members 33 within the bonding regions 322 and 323 are arranged at the separation distance “g” on the bottom B of the semiconductor device 3. The width W of the bonding prohibition region 321 may be greater than the separation distance “g”. More specifically, each of the bonding members 33 is disposed in a grid pattern within the bonding regions 322 and 323 other than the bonding prohibition region 321. That is, the bonding members 33 are located at intersection points of imaginary straight lines L within the bonding regions 322 and 323. The adjacent intersection points of the lines L have a pitch λ. On the other hand, a single row or column of bonding members 33 is prohibited from being disposed within the band-like bonding prohibition region 321. Accordingly, the width W of bonding prohibition region 321 is greater than the pitch λ between the straight lines L.

According to the circuit board assembly 1 of the embodiment, the distortion (strain) in bonding members 33 due to temperature changes is decreased as compared with a circuit board assembly without the bonding prohibition region 321. Accordingly, a solder ball failure such as falling out of the pad 33A or the terminal 21, and a crack of the solder ball 33B may be suppressed. Consequently, the reliability of connection between the semiconductor device 3 and the printed circuit board 2 is improved.

The inventors performed a simulation, and found that the distortion in bonding members 33 in the circuit board assembly 1 was reduced when the bonding prohibition region 321 is provided.

The reason the distortion in the bonding members 33 is reduced when providing the bonding prohibition region 321 will be described later.

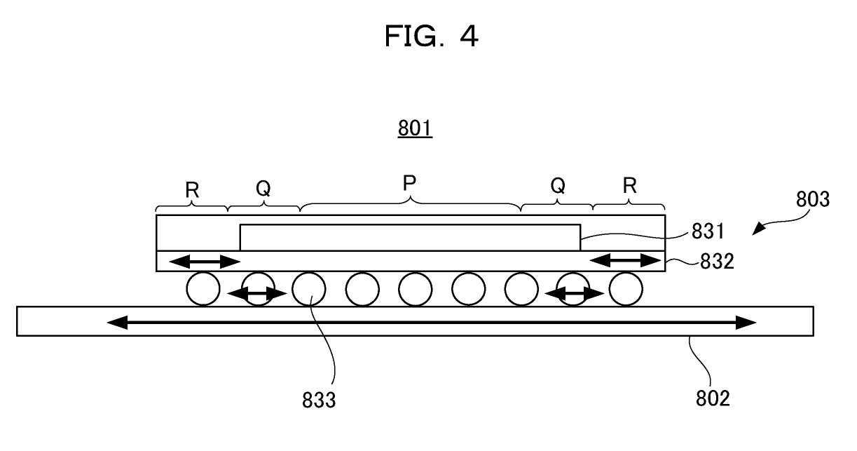

FIG. 4 is a cross-sectional view of a circuit board assembly of a comparative example. With the comparative example, distortion in bonding members will be explained.

Unlike the semiconductor device 3 of the embodiment, the circuit board assembly in FIG. 4 does not have a bonding prohibition region. Components of the circuit board assembly 801, for example a package substrate 832, a printed circuit board 802 and a semiconductor element 831 expand or contract as the assembly 801 is heated and cooled. The package substrate 832 and the printed circuit board 802 of resin have a higher thermal expansion coefficient than a semiconductor element 831 of silicon. Accordingly, a difference in coefficient of thermal expansion between the package substrate 832 and the semiconductor element 831 may cause distortion in the bonding members 833.

Specifically, since the semiconductor element 831 of silicon is fixed on the package substrate 832, the semiconductor element 831 tends to suppress a thermal expansion of the package substrate 832. Therefore, at the central area P of the semiconductor element 831, distortions of the bonding members 833 may be suppressed.

However, at the peripheral area Q of the semiconductor element 831, the difference in thermal expansion and contraction between the package substrate 832 and the semiconductor element 831 increases while the assembly 803 is heated and cooled. Accordingly, the distortion in the bonding member 833 may be significant at the peripheral area Q.

On the other hand, since both of the package substrate 832 and the circuit board 802 are formed of resin, both have a similar coefficient of thermal expansion. Therefore, at the outermost area R of the package substrate 832 (i.e., outside area from the periphery of the semiconductor element 831), distortion in bonding members 833 may be suppressed.

Consequently, the distortion occurs in the bonding members 833 provided in the overlapping region of the periphery of the semiconductor element 831.

As depicted in FIGS. 1 and 2A to 2C, according to the embodiment of the circuit board assembly 1 including the semiconductor device 3, the bonding members 33 are not disposed in the bonding prohibition region 321 where the periphery of the semiconductor element 31 is overlapped with the package substrate 32. Accordingly, the significant distortion of the bonding members may be prevented, and fractures and disconnection of bonding members due to thermal expansion may be suppressed. In addition, because the width W of the bonding prohibition region 321 is greater than the separation distance “g” as mentioned above, the distortion in the bonding members may be further reduced at the peripheral area where the periphery of the semiconductor element 31 is overlapped with the package substrate 32.

The inventors obtained distributions of distortions in the bonding members with respect to each of one simulation model of the embodiment and the other simulation model of the comparative example when the circuit board assembly is heated and cooled.

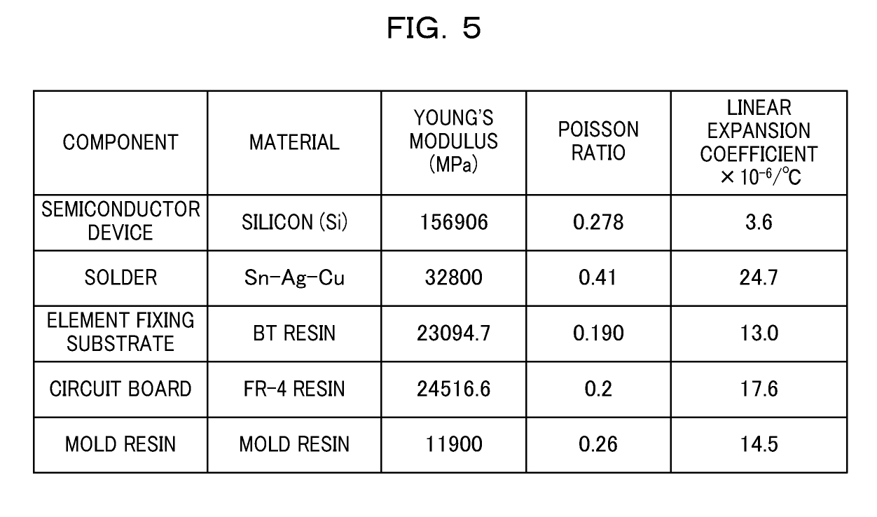

FIG. 5 illustrates a table indicating the material, Young's modulus, Poisson's ratio, and the linear expansion coefficient regarding each components of the circuit board assembly. For the sake of simplicity, the solder ball 33B was employed as the bonding member 33 in the simulation models. Young's modulus is defined as the ratio of the elastic stress over the strain (distortion) in the range of stress in which Hooke's Law holds. Poisson's ratio is defined as the ratio of the contraction or transverse strain (normal to the applied load), to the extension or axial strain (in the direction of the applied load).

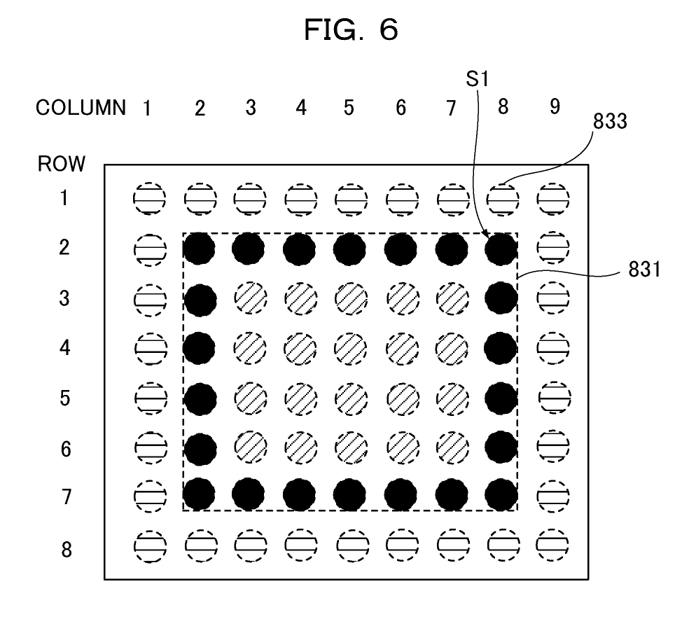

FIG. 6 illustrates a matrix arrangement of bonding members according to the comparative example, which does not provide a bonding prohibition region.

As a result of the simulation regarding the comparative example, a higher distortion distribution was obtained in the second and eighth columns and the second and seventh rows (black circles in FIG. 6) among the bonding members 833. In a plan view, the second and eighth columns and the second and seventh rows indicate the periphery of the semiconductor element 831. That is, it is shown that the maximum distortion among the bonding members 833 occurs in the periphery of the semiconductor element 831. In particular, the bonding member which is placed at a corner (e.g., the position S1 in FIG. 6) indicated the highest distortion over the entire semiconductor element 831.

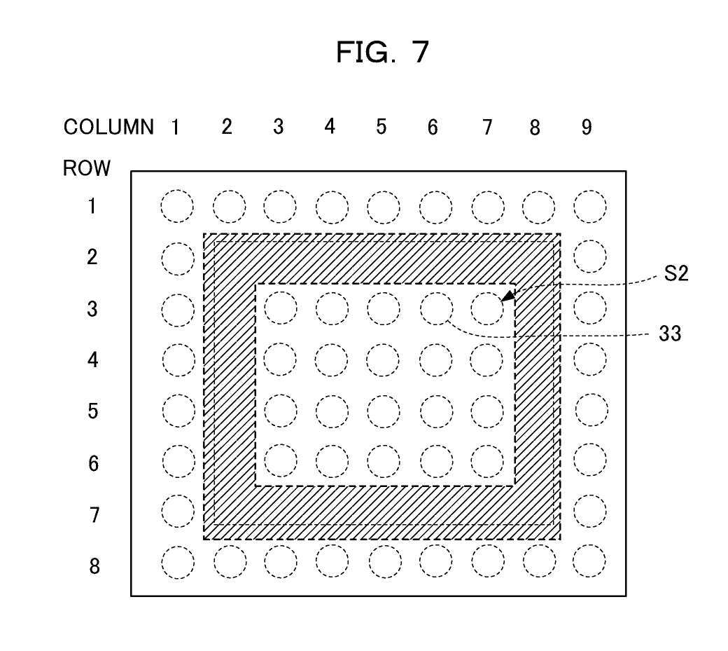

FIG. 7 illustrates a matrix arrangement of bonding members according to the embodiment having the bonding prohibition region.

As a result of the simulation regarding the embodiment, the maximum distortion in the bonding member 33 was obtained at the position S2 near a corner of the semiconductor element.

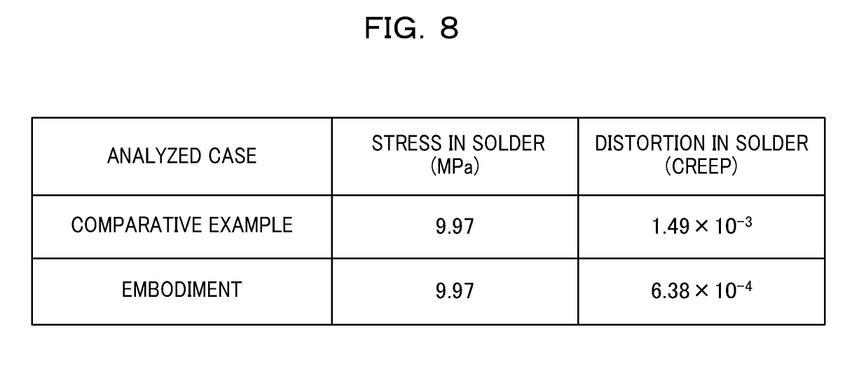

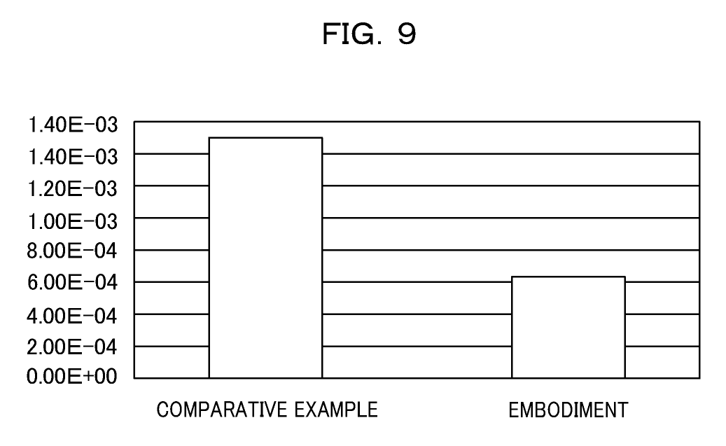

FIG. 8 illustrates the maximum distortion and stress values in the bonding members (solder joint) when the circuit board assembly was heated from 25° C. to 125° C. FIG. 9 is a graph comparing the maximum distortion obtained in the simulation models of the comparative example and the embodiment.

As depicted in FIGS. 8 and 9, the maximum distortion ratio according to the bonding members 833 of the comparative example reaches 1.49×10⁻³. On the other hand, according to the embodiment having a bonding prohibition region, the maximum distortion ratio of the bonding members 33 is reduced to 6.38×10⁻⁴.

In the embodiment, in case that the semiconductor element 31 is electrically connected to the package substrate 32 by flip chip method, a solder having a higher melting point than solder 33B may be employed to the semiconductor element 31.

In the embodiment, the package substrate 32 has a bonding region 323 outside the bonding prohibition region 321. Alternatively, the package substrate may provide another bonding prohibition region at the outermost bottom thereof. Another prohibition region may be regarded as a third region in the invention.

In the embodiment, the adjacent bonding members 33 have the same pitch λ at the intersection points of the lines L and/or have the same separation distance g. Alternatively, bonding members which are arranged inside the bonding prohibition region and outside the bonding prohibition region, in a plan view, may have different pitches and/or separation distances.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

1. A semiconductor device comprising:
a semiconductor element;
a package substrate on which the semiconductor element is fixed, the semiconductor element being fixed on the front surface of the package substrate, the package substrate having a first region and a second region on the back surface; and
a plurality of bonding members that is arranged in a grid pattern on the first region of the back surface of the package substrate,
wherein the second region of the package substrate defines a bonding prohibition region corresponding with the periphery of the semiconductor element in a plan view.

2. The semiconductor device according to claim 1, wherein the bonding prohibition region has a width greater than a pitch between adjacent bonding members within the first region.

3. The semiconductor device according to claim 2, wherein the first region of the back surface of the package substrate defines a central area of the semiconductor element and an outside area from the periphery of the semiconductor element.

4. The semiconductor device according to claim 1, wherein the package substrate has a greater size than the semiconductor element.

5. The semiconductor device according to claim 3, wherein the package substrate further includes a third region on the back surface, and
the third region defines another bonding prohibition region at an outermost area of the back surface of the package substrate.

6. The semiconductor device according to claim 3, wherein adjacent bonding members at the central area of the semiconductor element and at the outside area from the periphery of the semiconductor element have different pitches.

7. A circuit board assembly comprising:
a circuit board; and
a semiconductor device which is mounted on the circuit board, the semiconductor device having a semiconductor element; a package substrate on which the semiconductor element is fixed, the semiconductor element being fixed on the front surface of the package substrate, the package substrate having a first region and a second region on the back surface; and a plurality of bonding members that is arranged in a grid pattern on the first region of the back surface of the package substrate,
wherein the second region of the package substrate defines a bonding prohibition region corresponding with the periphery of the semiconductor element in a plan view.
